(19) United States
(12) Patent Application Publication
(10) Pub. No.: US 2024/0371663 A1
(43) Pub. Date: Nov. 7, 2024

(54) TEMPORARY CARRYING SUBSTRATE, CHIP TRANSFERRING DEVICE AND CHIP TRANSFERRING METHOD

(71) Applicants: ASTI GLOBAL INC., TAIWAN, Taichung City (TW); Skiileux Electricity Inc., Taoyuan City (TW)

(72) Inventors: CHIEN-SHOU LIAO, Taichung City (TW); YING-CHIEH CHEN, Taichung City (TW)

(21) Appl. No.: 18/618,151

(22) Filed: Mar. 27, 2024

Related U.S. Application Data
(60) Provisional application No. 63/463,893, filed on May 4, 2023.

(51) Int. Cl. H01L 21/67; B23K 1/005; H01L 21/683

(52) U.S. Cl. CPC H01L 21/67144; B23K 1/0056; H01L 21/67248; H01L 21/6835

(57) ABSTRACT

A temporary carrying substrate, a chip-transferring device and a chip transferring method are provided. The chip-transferring device includes a signal control module, a chip-carrying module and a chip-transferring module. The chip-transferring module is allowed to be configured to carry a temporary carrying substrate through the signal control module, and the temporary carrying substrate includes a plurality of micro heaters disposed thereinside or thereoutside. When the chip-transferring module needs to be configured to carry the temporary carrying substrate, a plurality of chips are arranged on a plurality of chip placement areas of the temporary carrying substrate and arranged in a predetermined arrangement shape. When the micro heater needs to be used, the micro heater is allowed to be configured to heat the temporary carrying substrate through the signal control module, thereby causing the temporary carrying substrate to generate thermal expansion to facilitate moving a corresponding one of the chips.

### CROSS-REFERENCE TO RELATED PATENT APPLICATION

This application claims the benefit of priority to the U.S. Provisional Patent Application Ser. No. 63/463,893, filed on May 4, 2023, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a carrying substrate, and more particularly to a temporary carrying substrate, a chip transferring device configured for using the temporary carrying substrate, and a chip transferring method configured for using the temporary carrying substrate.

### BACKGROUND OF THE DISCLOSURE

In the related art, multiple chips can be separated from each other by a predetermined distance by a pick-and-place method. However, the prior chip arrangement method still has room for improvement.

### SUMMARY OF THE DISCLOSURE

In response to the above-referenced technical inadequacy, the present disclosure provides a temporary carrying substrate, a chip transferring device and a chip transferring method.

In order to solve the above-mentioned problems, one of the technical aspects adopted by the present disclosure is to provide a chip transferring device, which includes a signal control module, a chip carrying module and a chip transferring module. The chip carrying module is electrically connected to the signal control module. The chip transferring module is electrically connected to the signal control module and movably disposed at a predetermined position adjacent to the chip carrying module. When the chip carrying module needs to be used, the chip carrying module is allowed to be configured to carry a circuit substrate through the signal control module. When the chip transferring module needs to be used, the chip transferring module is allowed to be configured to carry a temporary carrying substrate through the signal control module, and the temporary carrying substrate includes a plurality of micro heaters disposed thereinside or thereoutside. When the chip transferring module needs to be configured to carry the temporary carrying substrate, a plurality of chips are arranged on a plurality of chip placement areas of the temporary carrying substrate and arranged in a predetermined arrangement shape, and the chips respectively correspond to the micro heaters. When the micro heater needs to be used, the micro heater is allowed to be configured to heat the temporary carrying substrate through the signal control module, thereby causing the temporary carrying substrate to generate thermal expansion to facilitate moving a corresponding one of the chips.

In order to solve the above-mentioned problems, another one of the technical aspects adopted by the present disclosure is to provide a temporary carrying substrate configured to be applied to a chip transferring device, characterized in that the temporary carrying substrate has a plurality of micro heaters, and the micro heater is configured to heat the temporary carrying substrate, thereby causing the temporary carrying substrate to generate thermal expansion.

In order to solve the above-mentioned problems, yet another one of the technical aspects adopted by the present disclosure is to provide a chip transferring method, which includes: providing a temporary carrying substrate, in which the temporary carrying substrate has a plurality of micro heaters, and a plurality of chips are arranged on the temporary carrying substrate and respectively correspond to the micro heaters; when one of the chips arranged on the temporary carrying substrate is determined to be an offset chip due to deviation from a corresponding one of the chip placement areas, the micro heater that corresponds to the offset chip is allowed to be configured to heat a partial area of the temporary carrying substrate through the signal control module, so that the partial area of the temporary carrying substrate generates thermal expansion due to the heating of the micro heater, thereby moving the offset chip to the corresponding one of the chip placement areas; transferring the temporary carrying substrate to a circuit substrate through a chip transferring module; and bonding the chips on the circuit substrate through a laser generating module.

In one of the possible or preferred embodiments, when one of the chips arranged on the temporary carrying substrate is determined to be an offset chip due to deviation from a corresponding one of the chip placement areas, the micro heater that corresponds to the offset chip is allowed to be configured to heat a partial area of the temporary carrying substrate through the signal control module, so that the partial area of the temporary carrying substrate generates thermal expansion due to the heating of the micro heater, thereby moving the offset chip to the corresponding one of the chip placement areas.

In one of the possible or preferred embodiments, after the offset chip needs to be moved to the corresponding one of the chip placement areas through the thermal expansion generated by the temporary carrying substrate, the chip transferring module is allowed to be configured to transfer the chips to the circuit substrate through the signal control module.

In one of the possible or preferred embodiments, the chip transferring device further includes a laser generating module, and the laser generating module is electrically connected to the signal control module and movably disposed above the chip carrying module.

In one of the possible or preferred embodiments, after the chip transferring module needs to be configured to transfer the chips to the circuit substrate through the signal control module, the laser generating module is allowed to be configured to generate a laser beam through the signal control module, so that a plurality of soldering materials are heated through the laser beam in sequence, thereby allowing each of the chips to bond on the circuit substrate by heating the corresponding one of the soldering materials through the laser beam.

In one of the possible or preferred embodiments, when the micro heaters are arranged outside the temporary carrying substrate, the micro heaters are arranged on an upper surface or a lower surface of the temporary carrying substrate.

In one of the possible or preferred embodiments, the temporary carrying substrate is electrically connected to the signal control module, and the temporary carrying substrate is made of metal, ceramic, glass or quartz with a known thermal expansion coefficient.

In one of the possible or preferred embodiments, the chips are adhered to the chip placement areas of the temporary carrying substrate through an adhesive layer.

In one of the possible or preferred embodiments, the micro heaters are arranged in a predetermined arrangement shape to correspond to the predetermined arrangement shape of the chips.

In one of the possible or preferred embodiments, the chip transferring device further includes an image capturing module, and the image capturing module is electrically connected to the signal control module.

In one of the possible or preferred embodiments, when the image capturing module needs to be used, the image capturing module is allowed to be configured to capture an image of the chips that are arranged on the temporary carrying substrate through the signal control module, thereby determining whether each of the chips deviates from a corresponding one of the chip placement areas through the signal control module.

Therefore, in the chip transferring device provided by the present disclosure, by virtue of “the chip transferring module being allowed to be configured to carry a temporary carrying substrate through the signal control module” and “the temporary carrying substrate including a plurality of micro heaters disposed thereinside or thereoutside,” the micro heater can be allowed to be configured to heat the temporary carrying substrate through the signal control module, thereby causing the temporary carrying substrate to generate thermal expansion to facilitate moving a corresponding one of the chips (thereby achieving the purpose of fine-tuning the position of the chips).

Furthermore, in the temporary carrying substrate provided by the present disclosure, by virtue of “the temporary carrying substrate having a plurality of micro heaters,” the micro heater can be allowed to be configured to heat the temporary carrying substrate, thereby causing the temporary carrying substrate to generate thermal expansion to facilitate moving a corresponding one of the chips (thereby achieving the purpose of fine-tuning the position of the chips).

Moreover, in the chip transferring method provided by the present disclosure, by virtue of “the temporary carrying substrate having a plurality of micro heaters” and “a plurality of chips being arranged on the temporary carrying substrate and respectively corresponding to the micro heaters,” the partial area of the temporary carrying substrate can generate thermal expansion due to the heating of the micro heater, thereby moving the offset chip to the corresponding one of the chip placement areas (thereby achieving the purpose of fine-tuning the position of the chips).

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a chip transferring method provided by a first embodiment of the present disclosure;

FIG. 2 is a functional block diagram of a chip transferring device according to the first embodiment of the present disclosure;

FIG. 3 is a schematic view of a temporary carrying substrate configured to carry multiple chips according to the first embodiment of the present disclosure;

FIG. 4 is a schematic view of an offset chip carried by the temporary carrying substrate deviating from the corresponding chip placement area according to the first embodiment of the present disclosure;

FIG. 5 is a schematic view of the offset chip carried by the temporary carrying substrate being moved to the range of the corresponding chip placement area according to the first embodiment of the present disclosure;

FIG. 6 is a schematic view of the chip transferring device using the chip transferring module to transfer the temporary carrying substrate to a circuit substrate according to the first embodiment of the present disclosure;

FIG. 7 is a schematic view of the chip transferring device using a laser generating module to bond the chips on the circuit substrate according to the first embodiment of the present disclosure;

FIG. 8 is a schematic view of the chip transferring device configured for removing the temporary carrying substrate through the chip transferring module according to the first embodiment of the present disclosure;

FIG. 9 is a schematic view of the temporary carrying substrate configured to carry the chips according to a second embodiment of the present disclosure; and

FIG. 10 is a schematic view of the temporary carrying substrate configured to carry the chips according to a third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

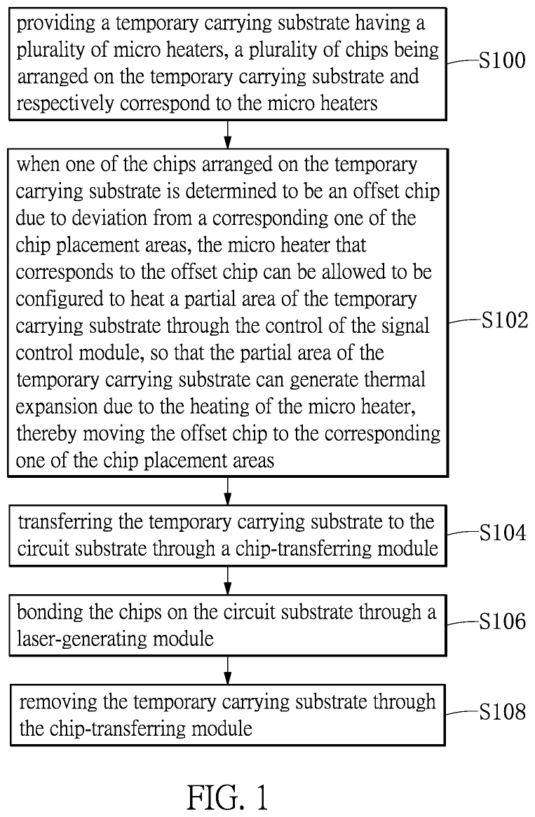

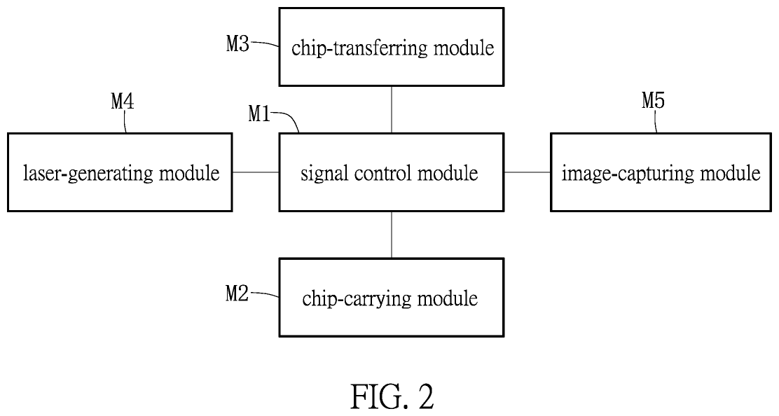

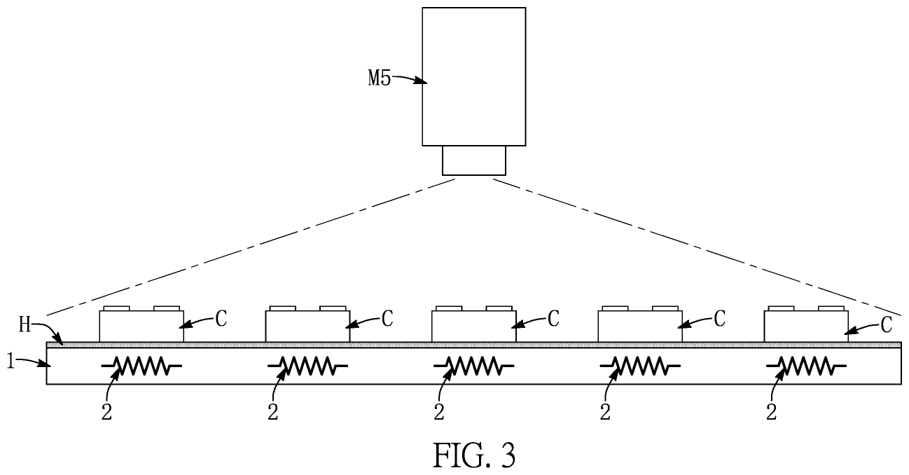

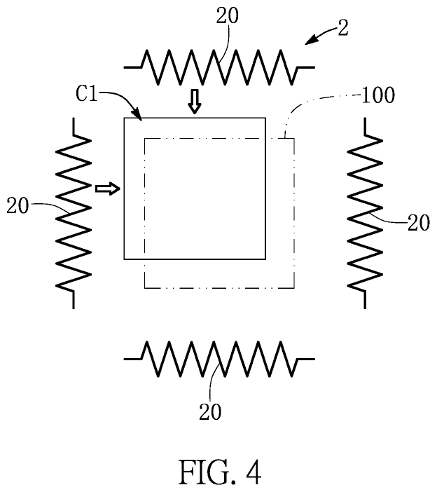

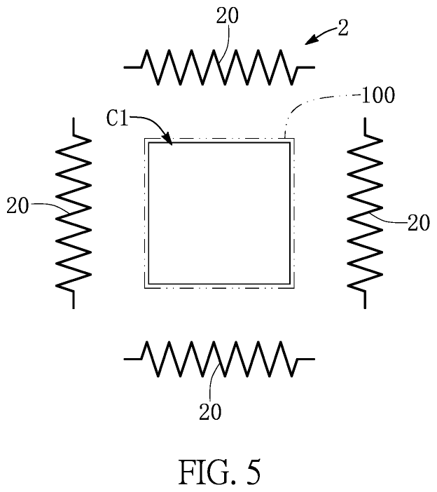

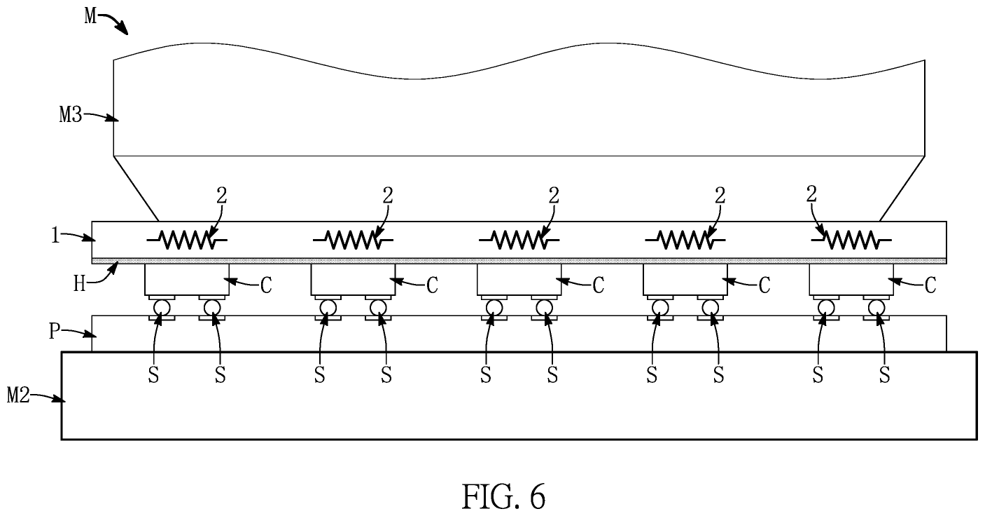

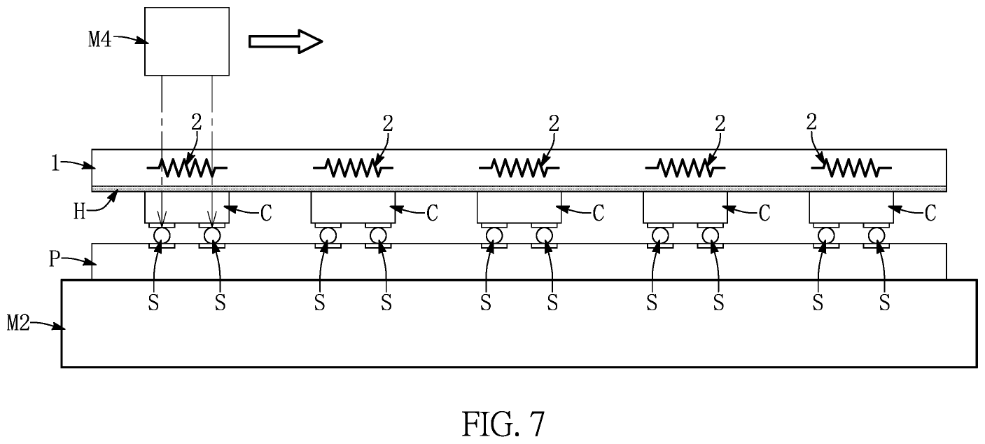

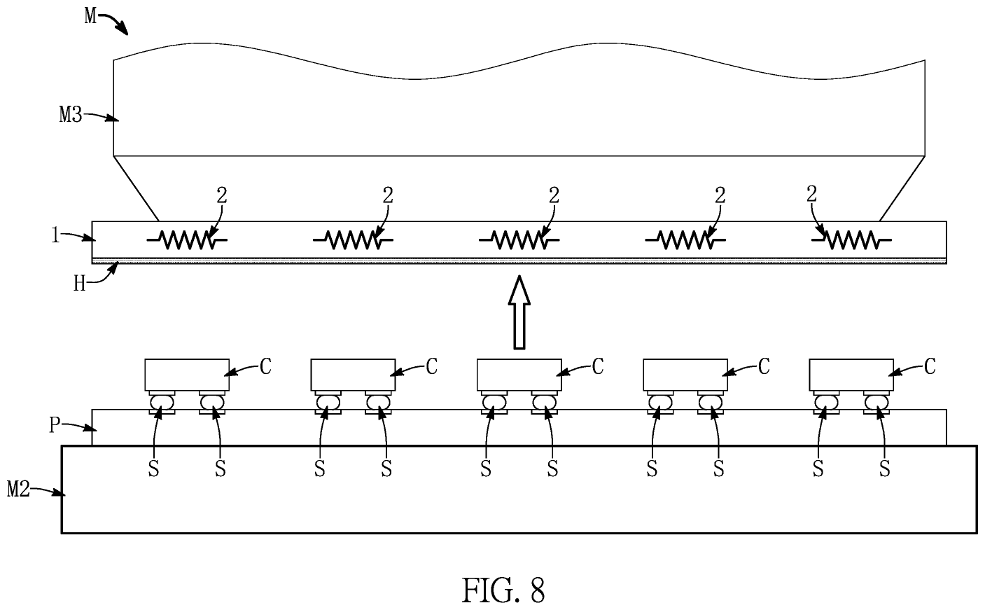

Referring to FIG. 1 to FIG. 8, a first embodiment of the present disclosure provides a chip transferring method, which may include the following steps: firstly, referring to FIG. 1, FIG. 2 and FIG. 3, providing a temporary carrying substrate 1, in which the temporary carrying substrate 1 has a plurality of micro heaters 2, and a plurality of chips C (such as multiple mini LED chips, multiple micro LED chips or any kind of semiconductor chips can be disposed on the temporary carrier substrate 1 through the adhesive layer H) are arranged on the temporary carrying substrate 1 and respectively correspond to the micro heaters 2 (step S100); next, referring to FIG. 1, FIG. 3, FIG. 4 and FIG. 5, when one (at least one) of the chips C arranged on the temporary carrying substrate 1 is determined to be an offset chip C1 due to deviation from a corresponding one of the chip placement areas 100 (that is to say, the offset chip C1 is not correctly arranged within the corresponding chip placement areas 100, but is offset relative to the corresponding chip placement areas 100 as shown in FIG. 4), the micro heater 2 (such as a micro heater 2 including a plurality of heating structures 20 separate from each other) that corresponds to the offset chip C1 can be allowed to be configured to heat a partial area of the temporary carrying substrate 1 through the control of the signal control module M1, so that the partial area of the temporary carrying substrate 1 can generate thermal expansion due to the heating of the micro heater 2 (that is to say, as shown in FIG. 4, a part of the temporary carrying substrate 1 can be heated through two of the heating structures 20 of the micro heater 2, and the direction of the arrow is the moving direction of the temporary carrying substrate 1 after thermal expansion), thereby moving the offset chip C1 to the corresponding one of the chip placement areas 100 (that is to say, as shown in FIG. 5, the offset chip C1 can be moved to the corresponding chip placement area 100 according to the movement of the temporary carrying substrate 1 after thermal expansion) (step S102); then, referring to FIG. 1, FIG. 2 and FIG. 6, carrying a circuit substrate P (such as any carrier substrate with circuit layouts) through a chip carrying module M2 (such as removable clamps, removable vacuum suction nozzles or any kind of removable stages), and transferring the temporary carrying substrate 1 to the circuit substrate P through a chip transferring module M3 (such as movable grippers, movable vacuum suction nozzles or any kind of chip transferring structures) (step S104) (it should be noted that during the period of transferring the temporary carrying substrate 1 to the circuit substrate P, the corresponding micro heater 2 is continuously turned on, so that the offset chip C1 can be maintained within the range of the corresponding chip placement area 100 as shown in FIG. 5); afterward, referring to FIG. 1, FIG. 2 and FIG. 7, bonding the chips C on the circuit substrate P through a laser generating module M4 (such as a laser focusing module with a fixed focusing processing head or any kind of laser light providing module) (step S106) (it should be noted that during the period of bonding the chips C on the circuit substrate P, the corresponding micro heater 2 is continuously turned on, so that the offset chip C1 can be maintained within the range of the corresponding chip placement area 100 as shown in FIG. 5); next, referring to FIG. 1, FIG. 2 and FIG. 8, removing the temporary carrying substrate 1 through the chip transferring module M3 (step S108), or after step S108, the chip transferring method provided by the first embodiment of the present disclosure can further include a cleaning step to remove residues that may remain on the outer surface of chip C (such as a part of the residual material of the adhesive layer H). However, the aforementioned details are disclosed for exemplary purposes only, and are not meant to limit the scope of the present disclosure.

For example, after the step S100 of providing the temporary carrying substrate 1 configure for carrying multiple chips C, the chip transferring method provided by the first embodiment of the present disclosure may further include a stretching step (belonging to a physical stretching action), thereby separating the plurality of chips C from each other by a predetermined distance by stretching the temporary carrying substrate 1. That is to say, the temporary carrying substrate 1 provided by the present disclosure can be configured to replace the traditional blue film, so that the chip transferring method provided by the first embodiment of the present disclosure can also initially adjust the distance between each two chips C (i.e., the step of roughly adjusting the position of each chip C) by stretching the temporary carrying substrate 1, and then heating the temporary carrying substrate 1 through the micro heater 2, thereby causing the temporary carrying substrate 1 to generate thermal expansion to facilitate the purpose of fine-tuning the position of each chip C, so that the multiple chips C can accurately meet the requirement of having a predetermined pixel pitch. In addition, after the step S100 of providing the temporary carrying substrate 1 configured for carrying a plurality of chips C, the chip transferring method provided by the first embodiment of the present disclosure may further include capturing the images of the chips C arranged on the temporary carrying substrate 1 through an image capturing module M5, thereby determining whether each chip C has deviated or offset (such as movement offset or rotation offset) from the corresponding chip placement area 100. In addition, as shown in FIG. 6, before the step S104 of transferring the temporary carrying substrate 1 to the circuit substrate P through the chip transferring module M3, a plurality of soldering materials S (such as a plurality of solder balls or any kind of a plurality of solder bodies) can be placed on the circuit substrate P or the chip C in advance. However, the aforementioned details are disclosed for exemplary purposes only, and are not meant to limit the scope of the present disclosure.

It should be noted that referring to FIG. 2 to FIG. 8, the first embodiment of the present disclosure provides a chip transferring device M, which includes a signal control module M1, a chip carrying module M2 and a chip transferring module M3, the chip carrying module M2 is electrically connected to the signal control module M1, and the chip transferring module M3 is electrically connected to the signal control module M1 and movably disposed at a predetermined position adjacent to the chip carrying module M2. More particularly, referring to FIG. 2 and FIG. 6, when the chip carrying module M2 needs to be used, the chip carrying module M2 can be allowed to be configured to carry a circuit substrate P through the control of the signal control module M1. Furthermore, referring to FIG. 2 and FIG. 6, or referring to FIG. 2 and FIG. 8, when the chip transferring module M3 needs to be used, the chip transferring module M3 can be allowed to be configured to carry a temporary carrying substrate 1 through the control of the signal control module M1, and the temporary carrying substrate 1 includes a plurality of micro heaters 2 disposed inside or outside the temporary carrying substrate 1. Moreover, referring to FIG. 2, FIG. 3 and FIG. 6, when the chip transferring module M3 needs to be configured to carry the temporary carrying substrate 1, a plurality of chips C can be arranged on a plurality of chip placement areas 100 of the temporary carrying substrate 1 and arranged in a predetermined arrangement shape, and the chips C can respectively correspond to the micro heaters 2. In addition, referring to FIG. 2, FIG. 3 and FIG. 4, when the micro heater 2 needs to be used, the micro heater 2 can be allowed to be configured to heat the temporary carrying substrate 1 through the control of the signal control module M1, thereby causing the temporary carrying substrate 1 to generate thermal expansion to facilitate moving a corresponding one of the chips C (that is to say, the corresponding one of the chips C can be moved due to the thermal expansion of the temporary carrying substrate 1 generated by at least one of the micro heaters 2).

For example, referring to FIG. 2, FIG. 4 and FIG. 5, when one or at least one of the chips C arranged on the temporary carrying substrate 1 is determined to be an offset chip C1 due to deviation from a corresponding one of the chip placement areas 100 (that is to say, when one or at least one of the chips C that is deviated or offset from a corresponding one of the chip placement areas 100 is determined to be an offset chip C1 as shown in FIG. 4), the micro heater 2 that corresponds to the offset chip C1 can be allowed to be configured to heat a partial area of the temporary carrying substrate 1 through the control of the signal control module M1, so that the partial area of the temporary carrying substrate 1 can generate thermal expansion due to the heating of the micro heater 2, thereby moving the offset chip C1 to the corresponding one of the chip placement areas 100 (as shown in FIG. 5). In addition, referring to FIG. 2, FIG. 3, FIG. 5 and FIG. 6, after the offset chip C1 needs to be moved to the corresponding one of the chip placement areas 100 through the thermal expansion that is generated by the temporary carrying substrate 1 (as shown in FIG. 5), the chip transferring module M3 can be allowed to be configured to transfer the chips C to the circuit substrate P through the control of the signal control module M1 (as shown in FIG. 6). It should be noted that as shown in FIG. 4 or FIG. 5, each micro heater 2 may include a plurality of heating structures 20 (for example, the heating structure 20 may be any conductive material capable of converting electrical energy into thermal energy) that are separated from each other and distributed in a predetermined arrangement shape, and some or all of the plurality of heating structures 20 of each micro heater 2 can be configured to heat a portion of the temporary carrying substrate 1, so that the portion of the temporary carrying substrate 1 can generate thermal expansion due to heating of two of the heating structures 20 (as shown in FIG. 4, two of the heating structures 20 of the micro heater 2 can heat a part of the temporary carrying substrate 1, and the direction of the arrow is the moving direction of the part of the temporary carrying substrate 1 after thermal expansion). However, the aforementioned details are disclosed for exemplary purposes only, and are not meant to limit the scope of the present disclosure.

For example, referring to FIG. 2, FIG. 3, FIG. 4, FIG. 6 and FIG. 7, the chip transferring device M further includes a laser generating module M4 (or a laser light generation module), and the laser generating module M4 is electrically connected to the signal control module M1 and movably disposed above the chip carrying module M2. More particularly, referring to FIG. 3, FIG. 6 and FIG. 7, after the chip transferring module M3 needs to be configured to transfer the chips C to the circuit substrate P through the control of the signal control module M1 (as shown in FIG. 6), the laser generating module M4 can be allowed to be configured to generate a laser beam L (such as a laser beam L that can be focused above or below the chip C so as to make the laser beam L generated by the laser generating module M4 cannot be focused on the chip C) through the control of the signal control module M1, so that a plurality of soldering materials S can be heated through the laser beam L in sequence, thereby allowing each of the chips C to bond on the circuit substrate P by heating the corresponding one of the soldering materials S through the laser beam L (as shown in FIG. 7). It should be noted that the vertical projections of the heating structures 20 of the micro heater 2 will not fall on the soldering materials S, thereby preventing the laser beam L generated by the laser generating module M4 from being obstructed or blocked by the heating structures 20 of the micro heater 2, so that the laser beam L generated by the laser generating module M4 can smoothly and unobstructedly pass through the temporary carrying substrate 1 and be projected on the soldering materials S. However, the aforementioned details are disclosed for exemplary purposes only, and are not meant to limit the scope of the present disclosure.

It should be noted that, for example, referring to FIG. 2, FIG. 6 and FIG. 7, when the chip transferring module M3 needs to be configured to transfer the chips C to the circuit substrate P through the control of the signal control module M1, the laser generating module M4 can be allowed to be configured to generate a laser beam L through the control of the signal control module M1, the laser beam L can be allowed to be focused at any position away from one of the chips C to form a light focusing area (for example, the laser beam L is allowed to be focused above one of the chips C to form a light focusing area; or, the laser beam L is allowed to be focused below one of the chips C to form a light focusing area; or any position surrounding one of the chips C) and a heat radiation area away from the light focusing area, and the soldering materials S can be allowed to be cured (such as melting and then solidifying) through a predetermined radiation temperature that is provided by the heat radiation area of the laser beam L, thereby making each of the chips C (such as, mini LED chips or micro LED chips) allowed to be bonded on the circuit substrate P through the soldering material S. Therefore, as shown in FIG. 2 and FIG. 7, when the laser generating module M4 needs to be configured to generate the laser beam L through the control of the signal control module 1, the light focusing area that is formed by focusing the laser beam L above the chip C can be away from the chips C by a predetermined distance, thereby preventing the chips C from being damaged by a high temperature of the light focusing area generated by the laser beam L. When the laser generating module M4 needs to be configured to generate the laser beam L through the control of the signal control module 1, the light focusing area (i.e., a virtual light focusing area) that is formed by focusing the laser beam L below the chip C can be away from the chips C by a predetermined distance, thereby preventing the chips C from being damaged by a high temperature of the light focusing area generated by the laser beam L. However, the aforementioned details are disclosed for exemplary purposes only, and are not meant to limit the scope of the present disclosure.

For example, referring to FIG. 2, FIG. 3, FIG. 4, FIG. 5 and FIG. 6, the chip transferring device M further includes an image capturing module M5, and the image capturing module M5 is electrically connected to the signal control module M1. More particularly, referring to FIG. 2, FIG. 3 and FIG. 4, when the image capturing module M5 needs to be used, the image capturing module M5 can be allowed to be configured to capture an image of the chips C that are arranged on the temporary carrying substrate 1 through the control of the signal control module M1, thereby determining whether each of the chips C deviates or offsets from a corresponding one of the chip placement areas 100 through the control of the signal control module M1. Moreover, referring to FIG. 2, FIG. 3 and FIG. 4, when one of the chips C arranged on the temporary carrying substrate 1 is determined to be an offset chip C1 due to deviation from a corresponding one of the chip placement areas 100 (as shown in FIG. 4), the micro heater 2 that corresponds to the offset chip C1 can be allowed to be configured to heat a partial area of the temporary carrying substrate 1 through the control of the signal control module M1, so that the partial area of the temporary carrying substrate 1 can generate thermal expansion due to the heating of the micro heater 2, thereby moving the offset chip C1 to the corresponding one of the chip placement areas 100 (as shown in FIG. 5). In addition, referring to FIG. 2, FIG. 5 and FIG. 6, after the offset chip C1 needs to be moved to the corresponding one of the chip placement areas 100 through the thermal expansion generated by the temporary carrying substrate 1 (as shown in FIG. 5), the chip transferring module M3 can be allowed to be configured to transfer the chips C to the circuit substrate P through the control of the signal control module M1 (as shown in FIG. 6). It should be noted that the image capturing module M5 is configured to capture images of the chips C disposed on the temporary carrying substrate 1 through the control of the signal control module M1, thereby determine whether the offset chip C1 is accurately moved to the range of the corresponding chip placement area 100 through the control of the signal control module M1 (as shown in FIG. 5). However, the aforementioned details are disclosed for exemplary purposes only, and are not meant to limit the scope of the present disclosure.

It should be noted that referring to FIG. 2 to FIG. 8, the first embodiment of the present disclosure further provides a temporary carrying substrate 1 configured to be applied to a chip transferring device M, and the temporary carrying substrate 1 has a plurality of micro heaters 2 disposed thereinside. For example, the temporary carrying substrate 1 is electrically connected to the signal control module M1, and the temporary carrying substrate 1 can be made of metal (such as aluminum foil or copper foil), ceramic, glass or quartz with a known thermal expansion coefficient (or a known ductility property, or a known heat transfer property). In addition, the chips C can be adhered to the chip placement areas 100 of the temporary carrying substrate 1 through an adhesive layer H, and the micro heaters 2 can be arranged in a predetermined arrangement shape to correspond to the predetermined arrangement shape of the chips C. Therefore, the micro heater 2 can be configured to heat the temporary carrying substrate 1, thereby causing the temporary carrying substrate 1 to generate thermal expansion to facilitate the purpose of fine-tuning the position of each chip C, so that the multiple chips C can accurately meet the requirement of having a predetermined pixel pitch.

### Second Embodiment

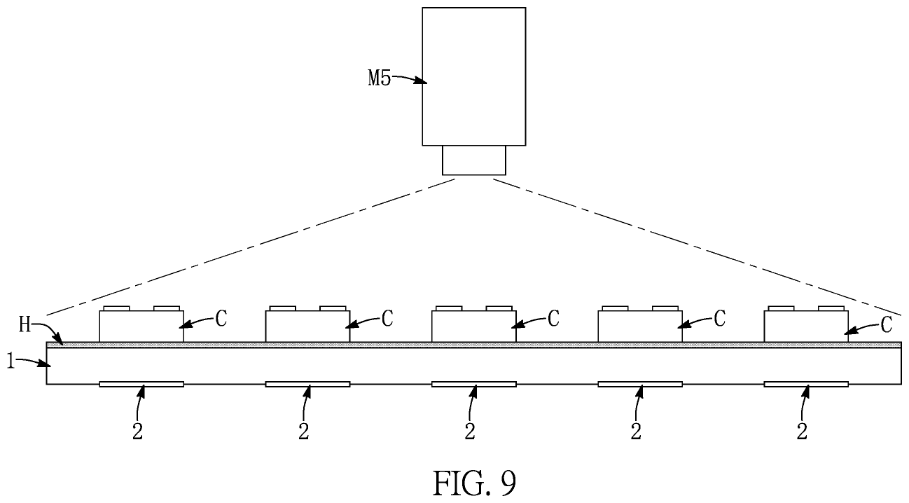

Referring to FIG. 9, a second embodiment of the present disclosure provides a temporary carrying substrate 1 configured to be applied to a chip transferring device (not shown). Comparing FIG. 9 with FIG. 3, the main difference between the second embodiment and the first embodiment is as follows: in the second embodiment, the temporary carrying substrate 1 has a plurality of micro heaters 2 disposed thereoutside. More particularly, when the micro heaters 2 are arranged outside the temporary carrying substrate 1, the micro heaters 2 can be arranged on a lower surface of the temporary carrying substrate 1 (or the micro heaters 2 can also be arranged on an upper surface and a lower surface of the temporary carrying substrate 1 at the same time). Therefore, the micro heater 2 can be configured to heat the temporary carrying substrate 1, thereby causing the temporary carrying substrate 1 to generate thermal expansion to facilitate the purpose of fine-tuning the position of each chip C, so that the multiple chips C can accurately meet the requirement of having a predetermined pixel pitch.

### Third Embodiment

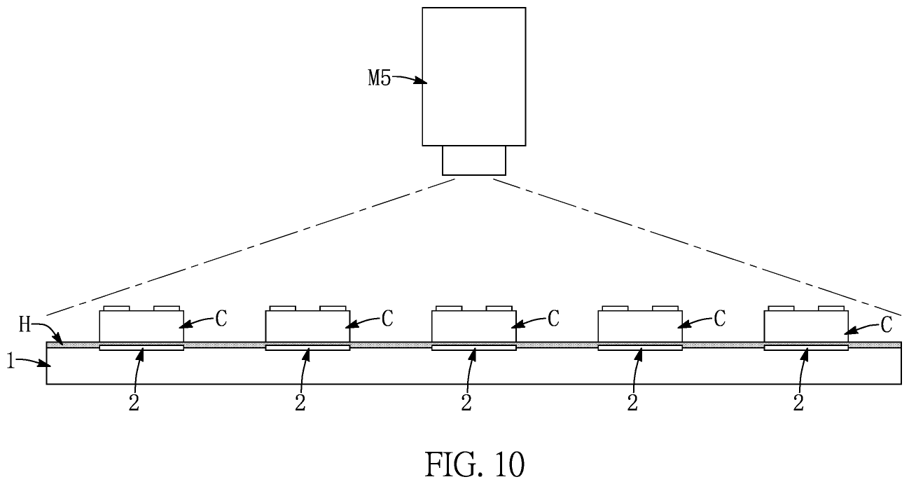

Referring to FIG. 10, a third embodiment of the present disclosure provides a temporary carrying substrate 1 configured to be applied to a chip transferring device (not shown). Comparing FIG. 10 with FIG. 3, the main difference between the third embodiment and the first embodiment is as follows: in the third embodiment, the temporary carrying substrate 1 has a plurality of micro heaters 2 disposed thereoutside. More particularly, when the micro heaters 2 are arranged outside the temporary carrying substrate 1, the micro heaters 2 can be arranged on an upper surface of the temporary carrying substrate 1 (or the micro heaters 2 can also be arranged on an upper surface and a lower surface of the temporary carrying substrate 1 at the same time). Therefore, the micro heater 2 can be configured to heat the temporary carrying substrate 1, thereby causing the temporary carrying substrate 1 to generate thermal expansion to facilitate the purpose of fine-tuning the position of each chip C, so that the multiple chips C can accurately meet the requirement of having a predetermined pixel pitch.

### Beneficial Effects of the Embodiments

In conclusion, in the chip transferring device M provided by the present disclosure, by virtue of “the chip transferring module M3 being allowed to be configured to carry a temporary carrying substrate 1 through the control of the signal control module M1” and “the temporary carrying substrate 1 including a plurality of micro heaters 2 disposed thereinside or thereoutside,” the micro heater 2 can be allowed to be configured to heat the temporary carrying substrate 1 through the control of the signal control module M1, thereby causing the temporary carrying substrate 1 to generate thermal expansion to facilitate moving a corresponding one of the chips C (thereby achieving the purpose of fine-tuning the position of the chips C).

Furthermore, in the temporary carrying substrate 1 provided by the present disclosure, by virtue of “the temporary carrying substrate 1 having a plurality of micro heaters 2,” the micro heater 2 can be allowed to be configured to heat the temporary carrying substrate 1, thereby causing the temporary carrying substrate 1 to generate thermal expansion to facilitate moving a corresponding one of the chips C (thereby achieving the purpose of fine-tuning the position of the chips C).

Moreover, in the chip transferring method provided by the present disclosure, by virtue of “the temporary carrying substrate 1 having a plurality of micro heaters 2” and “a plurality of chips C being arranged on the temporary carrying substrate 1 and respectively corresponding to the micro heaters 2,” the partial area of the temporary carrying substrate 1 can generate thermal expansion due to the heating of the micro heater 2, thereby moving the offset chip C1 to the corresponding one of the chip placement areas 100 (thereby achieving the purpose of fine-tuning the position of the chips C).

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A chip transferring device, comprising:
a signal control module;
a chip carrying module electrically connected to the signal control module; and
a chip transferring module electrically connected to the signal control module and movably disposed at a predetermined position adjacent to the chip carrying module;
wherein, when the chip carrying module needs to be used, the chip carrying module is allowed to be configured to carry a circuit substrate through the signal control module;
wherein, when the chip transferring module needs to be used, the chip transferring module is allowed to be configured to carry a temporary carrying substrate through the signal control module, and the temporary carrying substrate includes a plurality of micro heaters disposed thereinside or thereoutside;
wherein, when the chip transferring module needs to be configured to carry the temporary carrying substrate, a plurality of chips are arranged on a plurality of chip placement areas of the temporary carrying substrate and arranged in a predetermined arrangement shape, and the chips respectively correspond to the micro heaters;
wherein, when the micro heater needs to be used, the micro heater is allowed to be configured to heat the temporary carrying substrate through the signal control module, thereby causing the temporary carrying substrate to generate thermal expansion to facilitate moving a corresponding one of the chips.

2. The chip transferring device according to claim 1,
wherein, when one of the chips arranged on the temporary carrying substrate is determined to be an offset chip due to deviation from a corresponding one of the chip placement areas, the micro heater that corresponds to the offset chip is allowed to be configured to heat a partial area of the temporary carrying substrate through the signal control module, so that the partial area of the temporary carrying substrate generates thermal expansion due to the heating of the micro heater, thereby moving the offset chip to the corresponding one of the chip placement areas;
wherein, after the offset chip needs to be moved to the corresponding one of the chip placement areas through the thermal expansion generated by the temporary carrying substrate, the chip transferring module is allowed to be configured to transfer the chips to the circuit substrate through the signal control module.

3. The chip transferring device according to claim 1,
wherein the chip transferring device further includes a laser generating module, and the laser generating module is electrically connected to the signal control module and movably disposed above the chip carrying module;
wherein, after the chip transferring module needs to be configured to transfer the chips to the circuit substrate through the signal control module, the laser generating module is allowed to be configured to generate a laser beam through the signal control module, so that a plurality of soldering materials are heated through the laser beam in sequence, thereby allowing each of the chips to bond on the circuit substrate by heating the corresponding one of the soldering materials through the laser beam;
wherein, when the micro heaters are arranged outside the temporary carrying substrate, the micro heaters are arranged on an upper surface or a lower surface of the temporary carrying substrate;
wherein the temporary carrying substrate is electrically connected to the signal control module, and the temporary carrying substrate is made of metal, ceramic, glass or quartz with a known thermal expansion coefficient;
wherein the chips are adhered to the chip placement areas of the temporary carrying substrate through an adhesive layer;
wherein the micro heaters are arranged in a predetermined arrangement shape to correspond to the predetermined arrangement shape of the chips.

4. The chip transferring device according to claim 1,
wherein the chip transferring device further includes an image capturing module, and the image capturing module is electrically connected to the signal control module;
wherein, when the image capturing module needs to be used, the image capturing module is allowed to be configured to capture an image of the chips that are arranged on the temporary carrying substrate through the signal control module, thereby determining whether each of the chips deviates from a corresponding one of the chip placement areas through the signal control module;
wherein, when one of the chips arranged on the temporary carrying substrate is determined to be an offset chip due to deviation from a corresponding one of the chip placement areas, the micro heater that corresponds to the offset chip is allowed to be configured to heat a partial area of the temporary carrying substrate through the signal control module, so that the partial area of the temporary carrying substrate generates thermal expansion due to the heating of the micro heater, thereby moving the offset chip to the corresponding one of the chip placement areas;
wherein, after the offset chip needs to be moved to the corresponding one of the chip placement areas through the thermal expansion generated by the temporary carrying substrate, the chip transferring module is allowed to be configured to transfer the chips to the circuit substrate through the signal control module.

5. A temporary carrying substrate configured to be applied to a chip transferring device, characterized in that the temporary carrying substrate has a plurality of micro heaters, and the micro heater is configured to heat the temporary carrying substrate, thereby causing the temporary carrying substrate to generate thermal expansion.

6. The temporary carrying substrate according to claim 5,
wherein the chip transferring device includes a signal control module, a chip carrying module and a chip transferring module, the chip carrying module is electrically connected to the signal control module, and the chip transferring module is electrically connected to the signal control module and movably disposed at a predetermined position adjacent to the chip carrying module;
wherein, when the chip carrying module needs to be used, the chip carrying module is allowed to be configured to carry a circuit substrate through the signal control module;
wherein, when the chip transferring module needs to be used, the chip transferring module is allowed to be configured to carry the temporary carrying substrate through the signal control module, and the micro heaters disposed inside or outside the temporary carrying substrate;
wherein, when the chip transferring module needs to be configured to carry the temporary carrying substrate, a plurality of chips are arranged on a plurality of chip placement areas of the temporary carrying substrate and arranged in a predetermined arrangement shape, and the chips respectively correspond to the micro heaters;
wherein, when the micro heater needs to be used, the micro heater is allowed to be configured to heat the temporary carrying substrate through the signal control module, thereby causing the temporary carrying substrate to generate thermal expansion to facilitate moving a corresponding one of the chips.

7. The temporary carrying substrate according to claim 6,
wherein, when one of the chips arranged on the temporary carrying substrate is determined to be an offset chip due to deviation from a corresponding one of the chip placement areas, the micro heater that corresponds to the offset chip is allowed to be configured to heat a partial area of the temporary carrying substrate through the signal control module, so that the partial area of the temporary carrying substrate generates thermal expansion due to the heating of the micro heater, thereby moving the offset chip to the corresponding one of the chip placement areas;
wherein, after the offset chip needs to be moved to the corresponding one of the chip placement areas through the thermal expansion generated by the temporary carrying substrate, the chip transferring module is allowed to be configured to transfer the chips to the circuit substrate through the signal control module.

8. The temporary carrying substrate according to claim 6,
wherein the chip transferring device further includes a laser generating module, and the laser generating module is electrically connected to the signal control module and movably disposed above the chip carrying module;
wherein, after the chip transferring module needs to be configured to transfer the chips to the circuit substrate through the signal control module, the laser generating module is allowed to be configured to generate a laser beam through the signal control module, so that a plurality of soldering materials are heated through the laser beam in sequence, thereby allowing each of the chips to bond on the circuit substrate by heating the corresponding one of the soldering materials through the laser beam;
wherein, when the micro heaters are arranged outside the temporary carrying substrate, the micro heaters are arranged on an upper surface or a lower surface of the temporary carrying substrate;
wherein the temporary carrying substrate is electrically connected to the signal control module, and the temporary carrying substrate is made of metal, ceramic, glass or quartz with a known thermal expansion coefficient;
wherein the chips are adhered to the chip placement areas of the temporary carrying substrate through an adhesive layer;
wherein the micro heaters are arranged in a predetermined arrangement shape to correspond to the predetermined arrangement shape of the chips.

9. The temporary carrying substrate according to claim 6,
wherein the chip transferring device further includes an image capturing module, and the image capturing module is electrically connected to the signal control module;
wherein, when the image capturing module needs to be used, the image capturing module is allowed to be configured to capture an image of the chips that are arranged on the temporary carrying substrate through the signal control module, thereby determining whether each of the chips deviates from a corresponding one of the chip placement areas through the signal control module;
wherein, when one of the chips arranged on the temporary carrying substrate is determined to be an offset chip due to deviation from a corresponding one of the chip placement areas, the micro heater that corresponds to the offset chip is allowed to be configured to heat a partial area of the temporary carrying substrate through the signal control module, so that the partial area of the temporary carrying substrate generates thermal expansion due to the heating of the micro heater, thereby moving the offset chip to the corresponding one of the chip placement areas;
wherein, after the offset chip needs to be moved to the corresponding one of the chip placement areas through the thermal expansion generated by the temporary carrying substrate, the chip transferring module is allowed to be configured to transfer the chips to the circuit substrate through the signal control module.

10. A chip transferring method, comprising:
providing a temporary carrying substrate, wherein the temporary carrying substrate has a plurality of micro heaters, and a plurality of chips are arranged on the temporary carrying substrate and respectively correspond to the micro heaters;
when one of the chips arranged on the temporary carrying substrate is determined to be an offset chip due to deviation from a corresponding one of the chip placement areas, the micro heater that corresponds to the offset chip is allowed to be configured to heat a partial area of the temporary carrying substrate through the signal control module, so that the partial area of the temporary carrying substrate generates thermal expansion due to the heating of the micro heater, thereby moving the offset chip to the corresponding one of the chip placement areas;
transferring the temporary carrying substrate to a circuit substrate through a chip transferring module; and
bonding the chips on the circuit substrate through a laser generating module.
